(19) United States
(12) Patent Application Publication
(10) Pub. No.: US 2024/0224618 A1
(43) Pub. Date: Jul. 4, 2024

(54) DISPLAY APPARATUS

(71) Applicant: LG Display Co., Ltd., Seoul (KR)

(72) Inventors: Intae KO, Daegu (KR); ByungJune MUN, Chilgok-gun, Gyeongsangbuk-do (KR)

(21) Appl. No.: 18/393,403

(22) Filed: Dec. 21, 2023

(30) Foreign Application Priority Data
Dec. 30, 2022 (KR) 10-2022-0191271

(51) Int. Cl. H10K 59/123; H10K 59/122; H10K 102/00

(52) U.S. Cl. CPC H10K 59/123; H10K 59/122; H10K 2102/3026

(57) ABSTRACT

A display apparatus according to embodiments of the present specification may include a thin-film transistor disposed on a substrate, a first protective layer disposed on the thin-film transistor and including a first contact hole configured to expose a connection electrode of the thin-film transistor, a second protective layer disposed on the first protective layer and including an opening configured to expose the first protective layer and a second contact hole configured to expose the first contact hole, and a light-emitting element disposed on the opening. A first electrode of the light-emitting element may be disposed in an area including the opening and the first and second contact holes and connected to the connection electrode through the first and second contact holes.

### CROSS REFERENCE TO RELATED APPLICATION

This application claims priority from Korean Patent Application No. 10-2022-0191271, filed on Dec. 30, 2022, which is hereby incorporated by reference for all purposes as if fully set forth herein.

### BACKGROUND

### Technical Field

The present specification relates to a display apparatus.

### Description of the Related Art

With the development of information society, demands for display apparatuses for displaying images are increasing in various forms. Accordingly, various display apparatuses such as liquid crystal display (LCD) apparatuses, inorganic light-emitting display apparatuses, and organic light-emitting display (OLED) apparatuses have recently been used.

Among the display apparatuses, the OLED apparatuses are self-illuminating apparatuses and thus have a superior viewing angle, a high contrast ratio, and the like compared to the LCD apparatuses and can be decreased in weight and thickness and are advantageous in power consumption because a separate backlight is not required. In addition, the OLED apparatuses can be driven with a low direct current (DC) voltage, have a quick response time, and have low manufacturing costs.

### BRIEF SUMMARY

In the field of display technology, a technique for increasing light extraction efficiency of a display apparatus is being studied. The inventors of the present disclosure have provided various embodiments of a display apparatus that have increased light extraction efficiency. The various embodiments of the display apparatus provided herein also address one or more technical problems in the related art including the problems identified below.

For example, an organic light-emitting display apparatus includes an emission layer that emits light, but a problem in which light extraction efficiency of the organic light-emitting display apparatus is degraded due to the presence of light emitted from the emission layer without being emitted to the outside may arise.

Further, the organic light-emitting display apparatus may have a problem of increasing process time and costs and increasing a unit cost of a product due to a large number of process steps and masks required for connecting a light-emitting element and thin-film transistors.

Accordingly, the inventors of the present specification have provided several embodiments of a display apparatus capable of increasing light extraction efficiency by forming a second protective layer having an opening corresponding to an emission area, disposing a first electrode on the opening of the second protective layer, and configuring the first electrode to have an inclined portion at an edge of the emission area, thereby allowing light emitted from an emission layer to be reflected by the inclined portion of the first electrode.

In addition, the inventors of the present specification have provided several embodiments of a display apparatus allowing a process to be simplified and the number of used masks to be reduced.

The embodiments of the present specification provide a display apparatus allowing a process to be simplified and the number of used masks to be reduced.

Further embodiments of the present specification provide a display apparatus capable of preventing an undercut from occurring at a boundary of a first contact hole and a second contact hole so that a disconnection of the first electrode due to the undercut is prevented, and preventing a connection failure between a light-emitting element and a thin-film transistor due to the disconnection of the first electrode.

The embodiments of the present specification provide a display apparatus capable of increasing light extraction efficiency.

The embodiments of the present specification provide a display apparatus capable of preventing a connection failure between a light-emitting element and a thin-film transistor.

The technical benefits to be achieved according to the embodiments of the present specification are not limited to the above-described benefits, and other benefits not described may be clearly understood from the following description by those skilled in the art to which the technical idea of the present specification pertains.

In an aspect, embodiments of the present specification provide a display apparatus including a thin-film transistor disposed on a substrate, a first protective layer disposed on the thin-film transistor and including a first contact hole configured to expose a portion of a connection electrode of the thin-film transistor, a second protective layer disposed on the first protective layer and including an opening configured to expose the first protective layer and a second contact hole configured to expose the first contact hole, and a light-emitting element disposed on the opening. A first electrode of the light-emitting element may be disposed in an area including the opening and the first and second contact holes and connected to the connection electrode through the first and second contact holes.

In another aspect, embodiments of the present specification provide a display apparatus including a first protective layer located on a substrate and including a first contact hole, a second protective layer located in a partial area on the first protective layer and including an opening and a second contact hole, and a first electrode disposed in an area including the opening, the first contact hole, and the second contact hole, and disposed along a first inclined surface of the second protective layer exposed by the opening and having a first inclination angle and a second inclined surface of the second protective layer exposed by the second contact hole and having a second inclination angle smaller than the first inclination angle.

According to embodiments of the present specification, there is an effect of providing a display apparatus allowing the number of process steps and masks required to connect a light-emitting element and thin-film transistors to be reduced by disposing a second contact hole, which is formed in a second protective layer, so as to overlap a first contact hole formed in a first protective layer below the second protective layer, and by directly connecting the first electrode to a substrate through the first and second contact holes without a separate contact.

In addition, according to embodiments of the present specification, there is an effect of providing a display apparatus capable of suppressing or preventing the generation of an undercut even when misalignment occurs between contact holes and suppressing or preventing a defect in which a first electrode is disconnected due to the undercut, by configuring a bottom portion of a second contact hole to have a larger dimension than a top portion of a first contact hole. Accordingly, there is an effect of optimizing a process.

In addition, according to embodiments of the present specification, there is an effect of providing a display apparatus capable of increasing light extraction efficiency by configuring a first inclined portion of a first electrode, which serves to reflect light emitted from an emission layer, to have a high inclination angle. Accordingly, there is an effect of reducing power.

In addition, according to embodiments of the present specification, there is an effect of providing a display apparatus capable of improving step coverage by configuring a sidewall of a second contact hole to have a low inclination angle, and suppressing or preventing a connection failure between a light-emitting element and a thin-film transistor by increasing the thickness of a first electrode formed on the sidewall of the second contact hole.

The effects of the present specification are not limited to the above-described effects, and other effects not described may be clearly understood from the following description by those of ordinary skill in the art.

### BRIEF DESCRIPTION OF THE SEVERAL VIEWS OF THE DRAWINGS

The above and other aspects, features and advantages of the present disclosure will be more apparent from the following detailed description taken in conjunction with the accompanying drawings, in which:

FIG. 1 is a view illustrating an example of a display apparatus according to embodiments of the present specification;

FIG. 2 is an equivalent circuit diagram of a sub-pixel in the display apparatus according to embodiments of the present specification;

FIG. 3 is a plan view of the display apparatus according to embodiments of the present specification;

FIG. 4 is a cross-sectional view taken along line A-A′ of FIG. 3;

FIG. 5A is an enlarged view of portion B of FIG. 4;

FIG. 5B is an enlarged view of portion C of FIG. 4;

FIG. 6 is a view illustrating that light emitted from the display apparatus according to embodiments of the present specification is reflected by a first electrode;

FIG. 7 is a plan view illustrating emission parts and a non-emission part of the display apparatus according to embodiments of the present disclosure;

FIG. 8 is a cross-sectional view of a display apparatus according to a first experimental example of the present specification;

FIGS. 9A and 9B are cross-sectional views illustrating a portion of a display apparatus according to a second experimental example of the present specification;

FIGS. 10A and 10B are cross-sectional views illustrating the display apparatus according to embodiments of the present specification in contrast to FIGS. 9A and 9B;

FIG. 11 is a view for describing some operations of a method of manufacturing the display apparatus according to embodiments of the present specification; and

FIG. 12 is a cross-sectional view of the display apparatus according to embodiments of the present specification.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present specification will be described in detail with reference to the accompanying drawings.

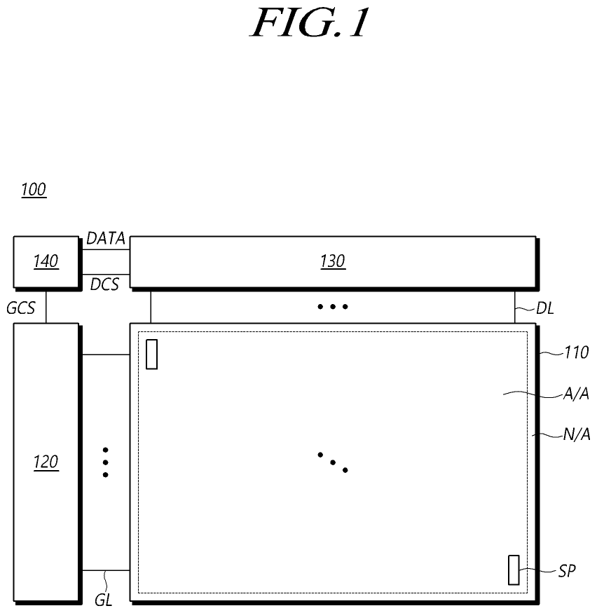

FIG. 1 is a view illustrating a schematic configuration of a display apparatus according to embodiments of the present specification.

Referring to FIG. 1, the display apparatus according to embodiments of the present specification includes a display panel 110 that includes an active area A/A in which a plurality of sub-pixels SP are disposed, and a non-active area N/A located outside the active area A/A. In addition, the display apparatus may include a gate driving circuit 120, a data driving circuit 130, a controller 140, and the like for driving various signal lines or the like disposed in the display panel 110.

In the display panel 110, a plurality of gate lines GL and a plurality of data lines DL are disposed, and the sub-pixel SP is disposed in an area in which the gate lines GL and the data lines DL are intersected.

The gate driving circuit 120 may be controlled by the controller 140, and may control driving timings of the plurality of sub-pixels SP by sequentially outputting a scan signal to the plurality of gate lines GL disposed in the display panel 110.

The gate driving circuit 120 may include one or more gate driver integrated circuits (GDICs), and may be located on only one side of the display panel 110, or may be located on both sides thereof according to a driving method.

Each of the GDICs may be connected to a bonding pad of the display panel 110 by a tape automated bonding (TAB) method or a chip-on-glass (COG) method. Alternatively, each GDIC may be implemented as a gate-in-panel (GIP) type and disposed directly on the display panel 110 or may be integrated and disposed on the display panel 110 in some cases. Further, each GDIC may be implemented by a chip-on-film (COF) method in which each GDIC is mounted on a film connected to the display panel 110.

The data driving circuit 130 receives image data from the controller 140 and converts the image data into an analog data voltage. In addition, the data driving circuit 130 outputs the data voltage to the respective data lines DL according to the timing at which the scan signal is applied through the gate lines GL, so that each of the sub-pixels SP expresses a brightness corresponding to the image data.

The data driving circuit 130 may include one or more source driver integrated circuits (SDICs).

Each of the SDICs may include a shift register, a latch circuit, a digital-to-analog converter, an output buffer, and the like.

Each SDIC may be connected to the bonding pad of the display panel 110 by a tape automated bonding (TAB) method or a chip-on-glass (COG) method. Alternatively, each SDIC may be disposed directly on the display panel 110, or may be integrated and disposed on the display panel 110 in some cases. Further, each SDIC may be implemented by a chip-on-film (COF) method, and in this case, the SDIC may be mounted on a film connected to the display panel 110 and electrically connected to the display panel 110 through wirings on the film.

The controller 140 may supply various control signals to the gate driving circuit 120 and the data driving circuit 130, and control operations of the gate driving circuit 120 and the data driving circuit 130.

The controller 140 may be mounted on a printed circuit board, a flexible printed circuit, or the like and electrically connected to the gate driving circuit 120 and the data driving circuit 130 through the printed circuit board, the flexible printed circuit, or the like.

The controller 140 may control the gate driving circuit 120 to output the scan signal according to the timing implemented in each frame, convert externally received image data to match a data signal format used by the data driving circuit 130, and output the converted image data to the data driving circuit 130.

The controller 140 may receive various timing signals including a vertical synchronization signal VSYNC, a horizontal synchronization signal HSYNC, an input data enable signal DE, a clock signal CLK, and the like from the outside (e.g., a host system).

The controller 140 may generate various control signals by using the various timing signals received from the outside, and may output the control signals to the gate driving circuit 120 and the data driving circuit 130.

As an example, in order to control the gate driving circuit 120, the controller 140 may output various gate control signals GCS including a gate start pulse GSP, a gate shift clock GSC, a gate output enable signal GOE, and the like.

Here, the gate start pulse GSP controls an operation start timing of one or more GDICs constituting the gate driving circuit 120. The gate shift clock GSC, which is a clock signal commonly input to one or more GDICs, controls a shift timing of the scan signal. The gate output enable signal GOE specifies timing information on one or more GDICs.

In addition, in order to control the data driving circuit 130, the controller 140 may output various data control signals DCS including a source start pulse SSP, a source sampling clock SSC, a source output enable signal SOE, and the like.

Here, the source start pulse SSP controls a data sampling start timing of one or more SDICs constituting the data driving circuit 130. The source sampling clock SSC is a clock signal for controlling a data sampling timing for each of the SDICs. The source output enable signal SOE controls an output timing of the data driving circuit 130.

The display apparatus may further include a power management integrated circuit for supplying various voltages or currents to the display panel 110, the gate driving circuit 120, the data driving circuit 130, and the like or controlling the various voltages or currents to be supplied thereto.

Each of the sub-pixels SP may be located adjacent to an overlap between the gate lines GL and the data lines DL and a liquid crystal or a light-emitting element may be disposed according to the type of the display apparatus.

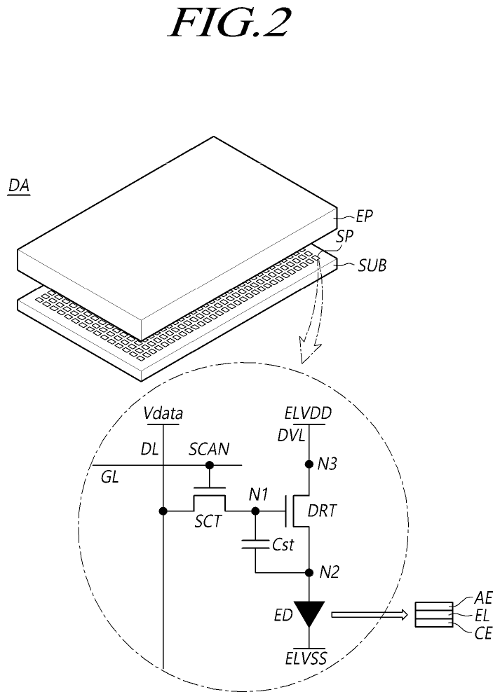

FIG. 2 is an equivalent circuit diagram of the sub-pixel SP, in the display apparatus 100 according to embodiments of the present specification.

The display panel may include a substrate SUB and an encapsulation layer EP. Each of the sub-pixels SP disposed in a display area DA of the substrate SUB may include a light-emitting element ED, a driving transistor DRT for driving the light-emitting element ED, a scan transistor SCT for transmitting a data voltage VDATA to a first node N1 of the driving transistor DRT, and a storage capacitor Cst for maintaining a constant voltage during one frame.

The driving transistor DRT may include the first node N1 to which the data voltage may be applied, a second node N2 electrically connected to the light-emitting element ED, and a third node N3 to which a driving voltage ELVDD is applied from a driving voltage line DVL. In the driving transistor DRT, the first node N1 may be a gate node, the second node N2 may be a source node or a drain node, and the third node N3 may be the drain node or the source node.

The light-emitting element ED may include a first electrode AE, an emission layer EL, and a second electrode CE. The first electrode AE may be a pixel electrode disposed in each sub-pixel SP, and may be electrically connected to the second node N2 of the driving transistor DRT of each sub-pixel SP. The second electrode CE may be a common electrode commonly disposed in the plurality of sub-pixels SP, and a base voltage ELVSS may be applied to the second electrode CE.

For example, the first electrode AE may be an anode. The second electrode CE may be a cathode. The first electrode AE may be a pixel electrode, and the second electrode CE may be a common electrode. On the contrary, the first electrode AE may be a common electrode, and the second electrode CE may be a pixel electrode. Hereinafter, for convenience of description, in the embodiments of the present specification, it is assumed that the first electrode AE is a pixel electrode and the second electrode CE is a common electrode.

For example, the light-emitting element ED may be an organic light-emitting diode (OLED), an inorganic light-emitting diode, or a quantum dot light-emitting element. In this case, when the light-emitting element ED is an organic light-emitting diode, the emission layer EL of the light-emitting element ED may include an organic emission layer including an organic material.

The scan transistor SCT may be on/off controlled by a scan signal SCAN, which is a gate signal, applied via the gate line GL and be electrically connected between the first node N1 of the driving transistor DRT and the data line DL.

The storage capacitor Cst may be electrically connected between the first node N1 and second node N2 of the driving transistor DRT.

Each sub-pixel SP may have a 2T (transistor) 1C (capacitor) structure that includes two transistors DRT and SCT and one capacitor Cst as shown in FIG. 2 and, in some cases, each sub-pixel SP may further include one or more transistors or one or more capacitors. The embodiments of the present specification are not limited thereto.

The storage capacitor Cst is not a parasitic capacitor (e.g., Cgs or Cgd) which is an internal capacitor that may be present between the first node N1 and the second node N2 of the driving transistor DRT but may be an external capacitor intentionally designed outside the driving transistor DRT.

Each of the driving transistor DRT and the scan transistor SCT may be an n-type transistor or a p-type transistor.

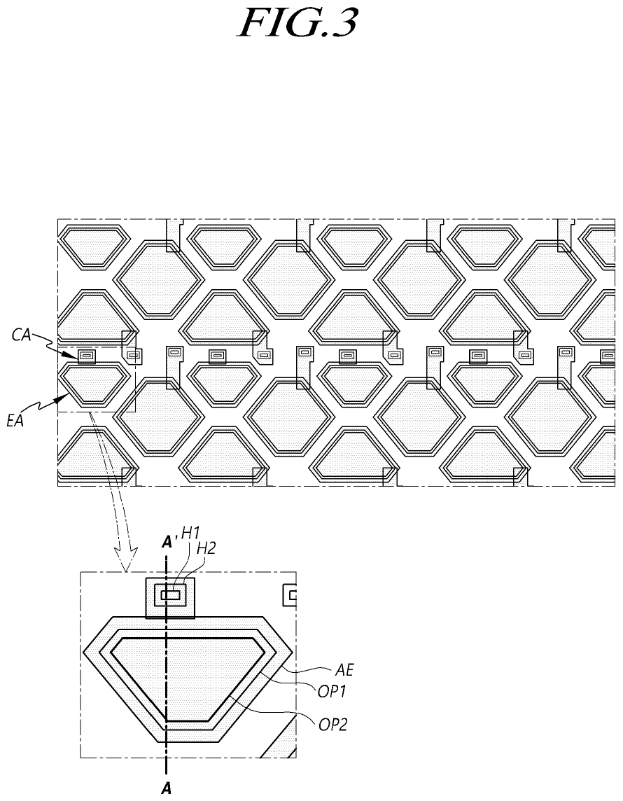

FIG. 3 is a plan view of the display apparatus according to embodiments of the present specification.

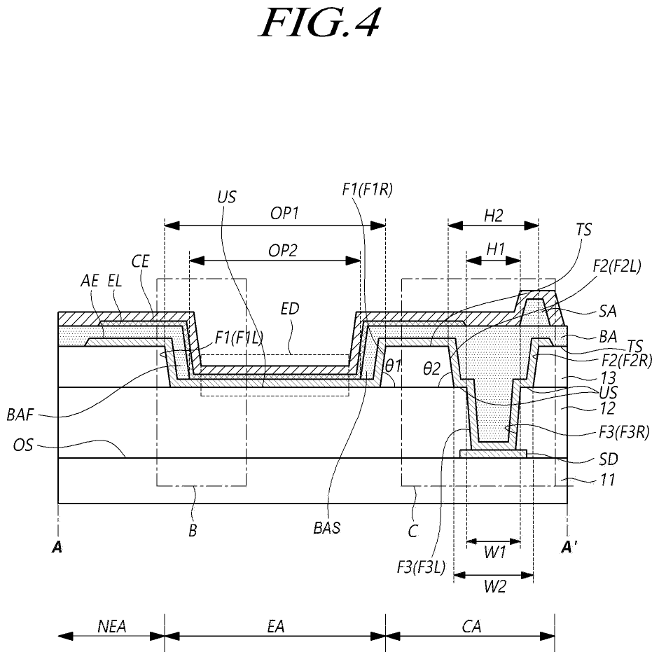

FIG. 4 is a cross-sectional view taken along line A-A′ of FIG. 3.

In order to simplify the drawing, FIG. 3 shows the first electrode AE, a first opening OP1 of a second protective layer, a second opening OP2 of a bank, a first contact hole H1 of a first protective layer, and a second contact hole H2 of the second protective layer from among components of the display apparatus.

Referring to FIG. 3, the substrate may include a plurality of emission areas EA and a plurality of contact areas CA.

The light-emitting element ED of the sub-pixel may be disposed in each of the plurality of emission areas EA.

Each of the plurality of sub-pixels may be defined as a minimum unit that emits light. The plurality of sub-pixels may include, for example, a red sub-pixel Red SP, a green sub-pixel Green SP, and a blue sub-pixel Blue SP. In addition, the plurality of sub-pixels may further include a white sub-pixel White SP. Each of the plurality of unit pixels may include at least three sub-pixels adjacent to each other.

The light-emitting element may include the first electrode AE, the emission layer EL, and the second electrode CE.

The contact area CA may be disposed to correspond to each emission area EA.

The emission area EA may be exposed by the second opening OP2 of the bank. A non-emission area NEA is an area around the emission area EA, and may surround the emission area EA. The bank may be disposed in the non-emission area to block light generation in the non-emission area NEA.

A portion of the first electrode AE of the light-emitting element may be disposed in the emission area EA.

The first electrode AE may have a side mirror structure in order to increase luminance by improving light extraction efficiency, lower power consumption, and provide a wide viewing angle. In order to form the side mirror structure, in the emission area, the first opening OP1 of the second protective layer may be formed below the first electrode AE and the first electrode AE may be disposed in an area including the first opening OP1 of the second protective layer.

The first electrode AE may extend from the emission area EA to the contact area CA and may be connected to, for example, a connection electrode SD on the substrate through the first and second contact holes H1 and H2 provided in the contact area CA. The connection electrode SD may be, for example, a source/drain electrode of a thin-film transistor. The connection electrode SD may include a metal.

The second contact hole H2 may pass through the second protective layer and expose the first contact hole H1 and the first protective layer around the first contact hole H1. An area of the first protective layer exposed through the second contact hole H2 may be smaller than an area of the first protective layer exposed through the first opening OP1. The first contact hole H1 may pass through the first protective layer from a lower portion of the second contact hole H2 and expose a portion of the connection electrode SD. A first protective layer 12 may include the first contact hole H1. A portion of the connection electrode SD may be exposed by the first and second contact holes H1 and H2. The first electrode AE may be connected to the connection electrode SD exposed through the first and second contact holes H1 and H2.

Referring to FIG. 4, the display apparatus may include a substrate 11. A circuit layer may be disposed on one surface of the substrate 11.

The circuit layer may include a pixel circuit connected to wirings such as data lines, gate lines, power lines, and the like, a gate driving part connected to the gate lines, and the like. The circuit layer may include circuit elements such as a transistor implemented as a thin-film transistor (TFT), a capacitor, and the like. The wirings and circuit elements of the circuit layer may be implemented using a plurality of insulating layers, two or more metal layers separated with the insulating layer interposed therebetween, and an active layer including a semiconductor material.

The first protective layer 12 may be disposed on the substrate 11.

The first protective layer 12 may be a first planarization layer. The first protective layer 12 may planarize one surface OS of the substrate 11 on which a metal electrode, such as the connection electrode SD or the like, is formed. The first protective layer 12 may include a photosensitive organic material. The first protective layer 12 may be formed of an insulating inorganic insulating film, such as silicon nitride (SiNx) or silicon oxide (SiOx), or an organic insulating film, such as polyacrylate and polyimide, and the embodiments of the present specification are not limited thereto.

Although FIG. 4 illustrates a case in which the first protective layer 12 has a single-layer structure, the first protective layer 12 may be configured as multiple layers as necessary as long as one surface of the substrate 11 on which the circuit layer is formed may be planarized.

In the contact area CA, the first protective layer 12 may have an opening that extends through the first protective layer 12 to form the first contact hole H1. The first electrode AE is disposed inside the opening of the first protective layer 12. An electrical connection between the first electrode AE and the connection electrode SD can be made at the first contact hole H1. A portion of the substrate 11 may be exposed by the first contact hole H1 of the first protective layer 12. The portion of the substrate 11 exposed by the first contact hole H1 may be the connection electrode SD of the thin-film transistor.

A second protective layer 13 may be disposed on the first protective layer 12. The second protective layer 13 may be a second planarization layer, and the embodiments of the present specification are not limited thereto. The second protective layer 13 may include a photosensitive organic material. The second protective layer 13 may be formed of an insulating inorganic insulating film, such as silicon nitride (SiNx) or silicon oxide (SiOx), or an organic insulating film, such as polyacrylate and polyimide, and the embodiments of the present specification are not limited thereto.

A portion of the second protective layer 13 corresponding to the emission area EA of the sub-pixel may be open to form the first opening OP1. A portion of an upper surface US of the first protective layer 12 may be exposed by the first opening OP1 of the second protective layer 13 and the second contact hole H2.

The first opening OP1 may have a tapered shape that decreases in width as it approaches an upper surface OS of the substrate 11. A side surface (first inclined surface) F1 (also referred to as “first inclined side surface F1”) of the second protective layer 13 may be exposed through the first opening OP1. The first inclined surface F1 of the second protective layer 13 may have an inclination angle smaller than 90 degrees with respect to the upper surface OS of the substrate 11.

The second protective layer 13 may be disposed on the first protective layer 12 and may include the first opening OP1 exposing the first protective layer 12 and the second contact hole H2 exposing the first contact hole H1.

A portion of the second protective layer 13 may be open to form the second contact hole H2. The first contact hole H1 and the upper surface US of the first protective layer 12 around the first contact hole H1 may be exposed by the second contact hole H2. An area of the upper surface US of the first protective layer 12 exposed by the second contact hole H2 may be smaller than an area of the upper surface US of the first protective layer 12 exposed by the first opening OP1.

The second contact hole H2 may have a tapered shape that decreases in width as it approaches the upper surface US of the first protective layer 12. A side surface (second inclined surface) F2 (also referred to as “second inclined side surface F2”) of the second protective layer 13 may be exposed through the second contact hole H2. The second inclined surface F2 of the second protective layer 13 may have an inclination angle smaller than 90 degrees with respect to the upper surface OS of the substrate 11.

The first contact hole H1 may have a tapered shape that decreases in width as it approaches the upper surface of the substrate 11. A side surface (third inclined surface) F3 (also referred to as “third inclined side surface F3”) of the first protective layer 12 may be exposed through the first contact hole H1. The third inclined surface F3 of the first protective layer 12 may have an inclination angle smaller than 90 degrees with respect to the upper surface OS of the substrate 11.

A bottom portion of the second contact hole H2 may have a dimension larger than that of a top portion of the first contact hole H1. For example, when the dimension of the top portion of the first contact hole H1 is W1 (e.g., width W1), the dimension of the bottom portion of the second contact hole H2 may be W2 (e.g., width W2) larger than W1. That is, a dimension of the second contact hole H2 in a first direction (e.g., width W2) is greater than a dimension of the first contact hole H1 in the first direction (e.g., width W1) such that the second contact hole fully overlaps the first contact hole from a plan view.

The second contact hole H2 may expose an outer periphery of the top portion of the first contact hole H1 and at least a portion of the upper surface of the first protective layer 12 around the outer periphery of the top portion of the first contact hole H1.

An outer periphery of the bottom portion of the second contact hole H2 may be located on the first protective layer 12. In this case, the entire first contact hole H1 is exposed through the second contact hole H2, and a phenomenon in which a portion of the first contact hole H1 is covered by the second protective layer 13, that is, an “undercut” does not occur.

Due to the difference in dimensions of the two contact holes (e.g., the first contact hole H1 and the second contact hole H2), when the first electrode AE is disposed over an upper surface (or a top surface) of the second protective layer 13, the second inclined surface F2 of the second protective layer 13, the upper surface US of the first protective layer 12 around the outer periphery of the top portion of the first contact hole H1, and the third inclined surface F3 of the first protective layer 12, the first electrode AE has a step-like shape formed at the outer periphery of the top portion of the first contact hole H1.

The first electrode AE of the light-emitting element ED may be disposed in an area including the first opening OP1 of the second protective layer 13 and the first and second contact holes H1 and H2. The first electrode AE may be a pixel electrode or an anode.

The first electrode AE may be disposed on the upper surface US of the first protective layer 12 and the first inclined surface F1 of the second protective layer 13, which are exposed through the first opening OP1. In addition, the first electrode AE may be disposed on the second inclined surface F2 of the second protective layer 13 exposed through the second contact hole H2. The first electrode AE may be continuously and contiguously disposed along the first inclined surface F1 of the second protective layer 13, an upper surface TS of the second protective layer 13 connected to the first inclined surface F1, and the second inclined surface F2 of the second protective layer 13 connected to the upper surface TS of the second protective layer 13.

In addition, the first electrode AE may be disposed along the third inclined surface F3 of the first protective layer 12 exposed through the first contact hole H1. The first electrode AE may be continuously disposed along the second inclined surface F2 of the second protective layer 13, the upper surface US of the first protective layer 12 connected to the second inclined surface F2, and the third inclined surface F3 of the first protective layer 12 connected to the upper surface US of the first protective layer 12.

In addition, the first electrode AE may be disposed on the connection electrode SD exposed through the first contact hole H1, and may be directly connected to the connection electrode SD.

A bank BA (or also referred to as a bank layer BA) may be disposed on the second protective layer 13 while covering a portion of the first electrode AE. The bank BA may cover the first electrode AE disposed on a sidewall of the first opening OP1. The bank BA may be disposed at an edge of the first opening OP1 of the second protective layer 13. The bank BA may cover the first electrode AE disposed on the first and second contact holes H1 and H2 and fill the first and second contact holes H1 and H2.

A plurality of spacers SA may be disposed on the bank BA between the plurality of sub-pixels. When the light-emitting element ED is formed in the sub-pixel, a fine metal mask (FMM), which is a deposition mask, may be used. In this case, the plurality of spacers SA may be disposed to prevent damage, which may occur while being in contact with the deposition mask, and to maintain a constant distance between the deposition mask and the substrate 11.

At least a portion of the first electrode AE disposed on a bottom surface of the first opening OP1 of the second protective layer 13 may be exposed through the opening of the bank BA. The emission layer EL may be located on the opening including a side surface of the bank BA and an inclined surface of the bank BA.

Referring to FIG. 4, at least some portion of the bank BA may be positioned between the first electrode AE and the emission layer EL. To be specific, some portion of the bank BA is disposed between the first inclined surface F1 of the second protective layer 13 and an inclined side surface of the emission layer EL that faces the first inclined surface F1 of the second protective layer 13.

The entire or a portion of the emission layer EL may be located between adjacent banks BA.

In the opening of the bank BA, the emission layer EL may be in contact with the first electrode AE. The second electrode CE may be disposed on the emission layer EL. The second electrode CE may be a cathode. The light-emitting element ED may be formed by the first electrode AE, the emission layer EL, and the second electrode CE.

The light-emitting element ED may be disposed on the first opening OP1 of the second protective layer 13.

Referring to FIG. 4, the second protective layer 13 has the first inclined surface F1 exposed through the first opening OP1 on one side and the second inclined surface F2 exposed through the second contact hole H2 on the opposite side. As shown, at least a portion of the bank BA is between the first inclined surface F1 of the second protective layer 13 and the emission layer EL.

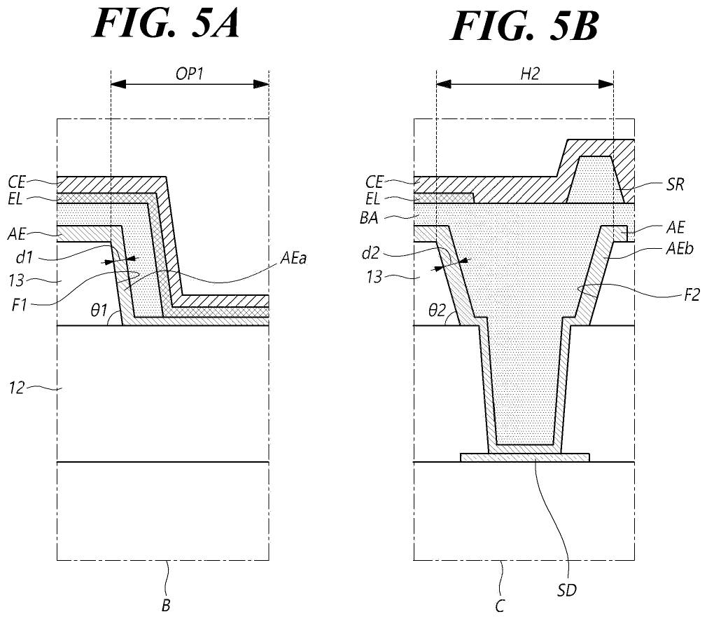

FIG. 5A is an enlarged view of portion B of FIG. 4. FIG. 5B is an enlarged view of portion C of FIG. 4.

Referring to FIG. 5A, the first inclined surface F1 of the second protective layer 13 exposed through the first opening OP1 may have a first inclination angle θ1 with respect to the upper surface US of the first protective layer 12. Referring to FIG. 5B, the second inclined surface F2 of the second protective layer 13 exposed through the second contact hole H2 may have a second inclination angle θ2, which is different from the first inclination angle θ1, with respect to the upper surface US of the first protective layer 12.

The first inclination angle θ1 may be larger than the second inclination angle θ2. For example, the first inclined surface F1 of the second protective layer 13 may have a steep slope, and the second inclined surface F2 of the second protective layer 13 may have a gentle slope.

The first electrode AE may include a first inclined portion AEa disposed on the first inclined surface F1 of the second protective layer 13 exposed through the first opening OP1 of the second protective layer 13, and a second inclined portion AEb disposed on the second inclined surface F2 of the second protective layer 13 exposed through the second contact hole H2.

The first inclined portion AEa of the first electrode AE may serve to reflect light emitted from the emission layer EL and extract the reflected light to the outside of the display apparatus. The second inclined portion AEb of the first electrode AE may serve to connect the light-emitting element ED and the connection electrode SD, for example, a source/drain electrode, of the thin-film transistor.

The first inclined portion AEa of the first electrode AE and the second inclined portion AEb of the first electrode AE may have different inclination angles. The first inclined portion AEa of the first electrode AE generated on the first inclined surface F1 of the second protective layer 13 may have a steep slope compared to that of the second inclined portion AEb of the first electrode AE. On the other hand, the second inclined portion AEb of the first electrode AE generated on the second inclined surface F2 of the second protective layer 13 may have a gentle slope compared to that of the first inclined portion AEa of the first electrode AE.

Since the first inclined portion AEa of the first electrode AE, which serves to reflect light emitted from the emission layer EL, has a steep slope, light extraction efficiency may be increased.

The first inclined portion AEa of the first electrode AE and the second inclined portion AEb of the first electrode AE may have different thicknesses. The first inclined portion AEa of the first electrode AE may have a first thickness d1. The second inclined portion AEb of the first electrode AE may have a second thickness d2 different from the first thickness d1. The second thickness d2 may be larger than the first thickness d1.

Since the second inclined surface F2 of the second protective layer 13 has a gentle slope and thus has excellent step coverage, the second inclined portion AEb of the first electrode AE may be generated to have a large thickness on the second inclined surface F2 of the second protective layer 13.

Since the first inclined surface F1 of the second protective layer 13 has a steep slope, the first inclined portion AEa of the first electrode AE generated on the first inclined surface F1 of the second protective layer 13 may have a small thickness. Since the first inclined portion AEa of the first electrode AE serves to reflect light emitted from the emission layer EL, it is acceptable for the first inclined portion AEa of the first electrode AE to have a small thickness.

Since the second inclined portion AEb of the first electrode AE serves to connect the light-emitting element and the thin-film transistor, a connection failure may occur when the thickness is small.

According to the present embodiments, since the second inclined surface F2 of the second protective layer 13 has a gentle slope, the second inclined portion AEb of the first electrode AE may be generated with a sufficiently large thickness on the second inclined surface F2 of the second protective layer 13, thereby preventing a connection failure between the light-emitting element and the thin-film transistor.

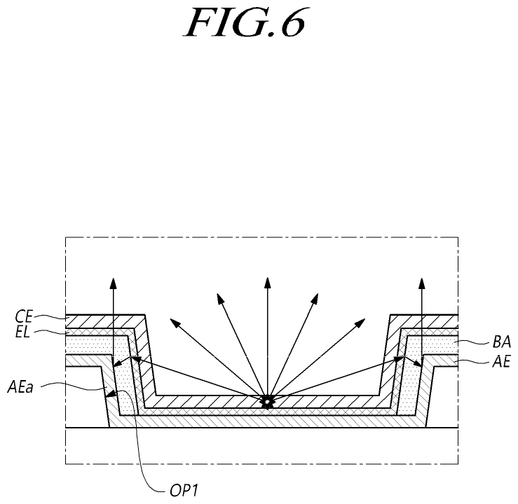

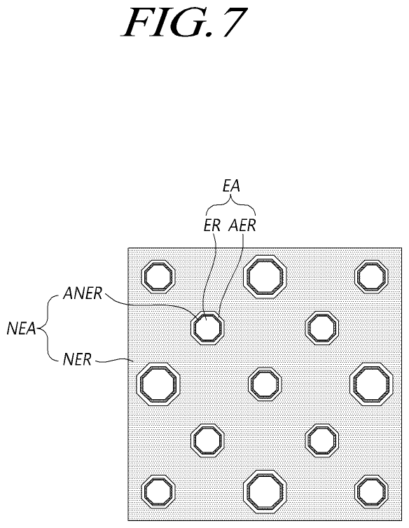

FIG. 6 is a view illustrating that light emitted from the emission layer EL according to embodiments of the present specification is reflected by the first electrode AE, and FIG. 7 is a plan view illustrating emission parts and a non-emission part of the display apparatus according to embodiments of the present disclosure.

Referring to FIG. 6, the light emitted from the emission layer EL is radiated in various directions without directivity in a specific direction. The light reaching the first inclined portion AEa of the first electrode AE may be reflected by the first inclined portion AEa and extracted to the outside of the display apparatus. Accordingly, the display apparatus according to embodiments of the present specification may have improved light extraction efficiency and thus have high luminance. In addition, since the light extraction efficiency is improved, a sufficient amount of light may be secured even with low power, thereby reducing power consumption. In addition, the present disclosure has an advantage of providing a wide viewing angle.

According to the present embodiments, since the first inclined surface F1 of the second protective layer 13 exposed by the first opening OP1 has a steep slope, the first inclined portion AEa of the first electrode generated on the first inclined surface F1 of the second protective layer 13 has a steep slope, thereby further improving the light extraction efficiency.

Referring to FIG. 7, a plurality of emission areas EA may be disposed in a display area to correspond to a plurality of sub-pixels. An area other than the plurality of emission areas EA may correspond to a non-emission area NEA. Areas of the emission areas EA of at least two sub-pixels may be different from each other, but the present specification is not limited thereto.

At least one emission area EA disposed in the display area may include a plurality of emission parts ER and AER. For example, one emission area EA may include an emission part ER and an additional emission part AER surrounding the emission part ER.

The non-emission area NEA may include a non-emission part NER and an additional non-emission part ANER.

The additional non-emission part ANER may be disposed between the emission part ER and the additional emission part AER. For example, the emission part ER and the additional emission part AER may be distinguished through the additional non-emission part ANER. The additional non-emission part ANER may be smaller in area than the emission part ER.

The additional non-emission part ANER may be in a black state when the display apparatus is in an on state, or the additional non-emission part ANER may have a lower luminance than the emission part ER and the additional emission part AER due to light incident from at least one of the emission part ER and the additional emission part AER.

The non-emission part NER may be disposed between the plurality of emission areas EA. For example, neighboring emission areas EA may be distinguished through the non-emission part NER.

The emission part ER may have an elliptical shape in a plan view. The additional non-emission part ANER and the additional emission part AER may be formed in an elliptical ring shape around the elliptical emission part ER. However, the embodiments of the present specification are not limited thereto, and the emission part ER may have a circular shape, an elliptical shape, or a polygonal shape, for example, a triangular shape, a quadrangular shape, an octagonal shape, or the like in a plan view, and a combination thereof is also possible. The shape of each of the additional non-emission part ANER and the additional emission part AER may vary according to the shape of the emission part ER.

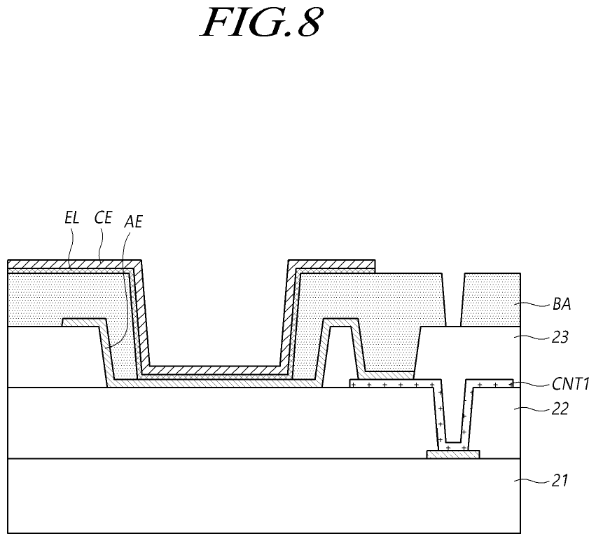

FIG. 8 is a cross-sectional view of a display apparatus according to a first experimental example of the present specification.

Referring to FIG. 8, the display apparatus according to the first experimental example may include a substrate 21, a first protective layer 22, a second protective layer 23, a contact CNT1, a first electrode AE, a bank layer BA, an emission layer EL, and a second electrode CE.

Unlike the embodiments of the present specification, in the display apparatus according to the first experimental example, the first electrode AE is connected to the connection electrode SD through the contact CNT1. Accordingly, the display apparatus according to the first experimental example does not have the structure in which the first electrode AE is directly connected to the connection electrode SD, which is a feature provided by the embodiments of the present specification.

The display apparatus according to the first experimental example has a problem that a process for forming the contact CNT1 and a mask for patterning the contact CNT1 are additionally required as compared to the display apparatus according to the embodiments of the present specification.

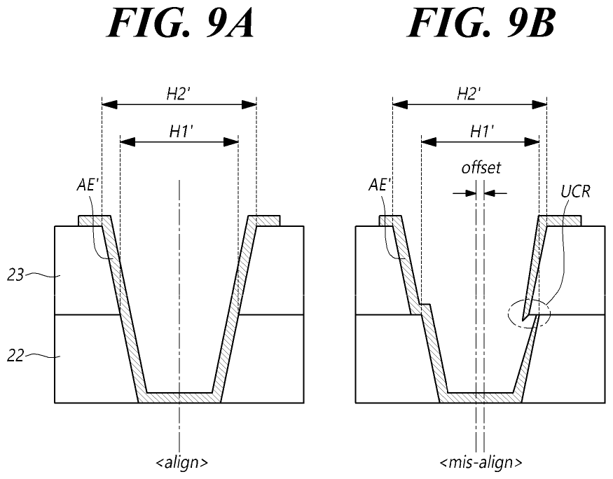

FIGS. 9A and 9B are cross-sectional views illustrating a portion of a display apparatus according to a second experimental example of the present specification.

Referring to FIG. 9A, in the display apparatus according to the second experimental example, a bottom portion of a second contact hole H2′ has the same dimension as a top portion of a first contact hole H1′.

This is not a problem when the first contact hole H1′ and the second contact hole H2′ are aligned, but when the second contact hole H2′ is offset to one side with respect to the first contact hole H1′ due to a process error or the like, resulting in a misalignment (see FIG. 9B), a portion of the top portion of the first contact hole H1′ may be disposed further outside of an outer periphery of a bottom portion of the second contact hole H2′. In this case, as shown in FIG. 9B, an undercut UCR in which a portion of the top portion of the first contact hole H1′ is covered by the second protective layer 23 may be generated, and a defect in which a first electrode AE′ is disconnected because deposition is not properly performed at a portion where the undercut is generated due to a shadow effect in a process of forming the first electrode AE′ may be generated.

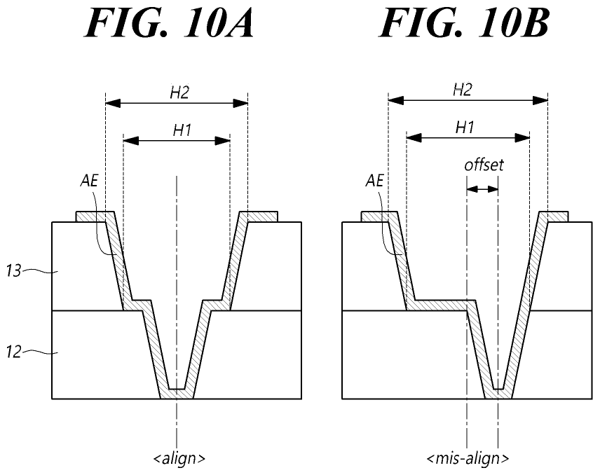

FIGS. 10A and 10B are cross-sectional views illustrating a portion of the display apparatus according to the present embodiments in contrast to FIGS. 9A and 9B.

Referring to FIG. 10A, in the display apparatus according to the present embodiments, the bottom portion of the second contact hole H2 has a larger dimension than the top portion of the first contact hole H1. For example, the first electrode AE may include a stair-shaped step.

The bottom portion of the second contact hole H2 may have a dimension of 2.5 μm or more in consideration of a process stability, but the embodiments of the present specification are not limited thereto.

Accordingly, even when a misalignment occurs between the first contact hole H1 and the second contact hole H2, as shown in FIG. 10B, there may be a margin, so that the top portion of the first contact hole H1 may not be covered by the second protective layer 13. That is, the generation of an undercut is suppressed or prevented.

According to embodiments of the present specification, by configuring the bottom portion of the second contact hole H2 to have a larger dimension than the top portion of the first contact hole H1, the generation of an undercut may be suppressed or prevented, and the generation of a defect in which the first electrode AE is disconnected due to the undercut may be suppressed or prevented as shown in FIGS. 10A and 10B.

Further, referring to FIG. 10B, the second inclined side surface F2 of the second protective layer 13 and the third inclined side surface F3 of the first protective layer 12 are coplanar with each other on one side. However, on the other side, a wider step is created compared to the step shown in FIG. 10A. This occurs when the alignment of the first contact hole H1 and the second contact hole H2 are not aligned as shown in FIG. 10A. For both the aligned case in FIG. 10A and the mis-aligned case in FIG. 10B, a dimension of the second contact hole H2 in a first direction is greater than a corresponding dimension of the first contact hole H1 in the first direction such that the second contact hole H2 fully overlaps the first contact hole H1 from a plan view.

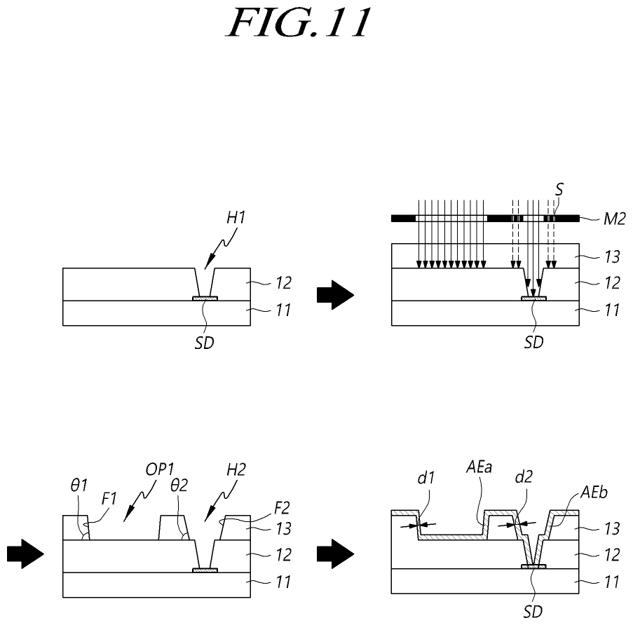

FIG. 11 is a view for describing some operations of a method of manufacturing the display apparatus according to embodiments of the present specification.

Referring to FIG. 11, the method of manufacturing the display apparatus according to embodiments of the present specification may include forming a first contact hole H1, which exposes a connection electrode SD in a first protective layer 12 stacked on a substrate 11 on which the connection electrode SD is provided, stacking a second protective layer 13 on the first protective layer 12 and exposing the second protective layer 13 using a mask pattern M2, developing and curing the exposed second protective layer 13, and forming a first electrode AE.

The forming of the first contact hole H1 may include exposing the first protective layer 12 corresponding to the first contact hole H1, developing the exposed first protective layer 12, and hard baking the developed first protective layer 12.

The mask pattern M2 used in the exposing of the second protective layer 13 may include an exposure area for defining the first opening OP1 and an exposure area for defining the second contact hole H2.

The exposure area for defining the first opening OP1 may correspond to an emission area of a light-emitting element. The exposure area for defining the second contact hole H2 may correspond to an area around the first contact hole H1 and the first contact hole H1. Accordingly, an area of the exposure area for defining the second contact hole H2 may be larger than an area of the top portion of the first contact hole H1.

The mask pattern M2 may include a transmittance adjustment area implemented as a slit pattern S at an edge of the exposure area for defining the second contact hole H2, and the transmittance adjustment area may not be provided at an edge of the exposure area for defining the first opening OP1.

The first opening OP1 and a second contact hole H2 may be formed in the second protective layer 13 by developing the exposed second protective layer 13 using the mask pattern M2.

The second protective layer 13 has a first inclined surface F1 exposed by the first opening OP1 and a second inclined surface F2 exposed by the second contact hole H2. Since the amount of exposure of the second protective layer 13 is reduced in the transmittance adjustment area, the second inclined surface F2 of the second protective layer 13 exposed by the second contact hole H2 has a gentle inclination angle. Since the transmittance adjustment area is not provided in the mask pattern M2 at the edge of the exposure area for defining the first opening OP1, the first inclined surface F1 of the second protective layer 13 exposed by the first opening OP1 has a steeper inclination angle than the second inclined surface F2 of the second protective layer 13.

When the first inclined surface F1 of the second protective layer 13 has a first inclination angle θ1, the second inclined surface F2 of the second protective layer 13 may have a second inclination angle θ2 smaller than the first inclination angle θ1.

Since the first inclined surface F1 of the second protective layer 13 has a steep slope, in the forming of the first electrode, the first electrode AE is generated with a steep slope on the first inclined surface F1 of the second protective layer 13. For example, a first inclined portion AEa of the first electrode AE generated on the first inclined surface F1 of the second protective layer 13 exposed through the first opening OP1 has a large inclination angle. Since the first inclined portion AEa of the first electrode AE, which serves to reflect light emitted from the emission layer EL, has a large inclination angle, light extraction efficiency may be improved.

Since the second inclined surface F2 of the second protective layer 13 has a gentle slope and thus has excellent step coverage, the first electrode AE is generated with a large thickness on the second inclined surface F2 of the second protective layer 13. For example, a second inclined portion AEb of the first electrode AE generated on the second inclined surface F2 of the second protective layer 13 exposed through the second contact hole H2 has a large thickness.

Since the second inclined portion AEb of the first electrode AE, which serves to electrically connect the light-emitting element and a thin-film transistor, has a large thickness, wiring resistance between the light-emitting element and the thin-film transistor may be lowered and a connection failure between the light-emitting element and the thin-film transistor may be prevented.

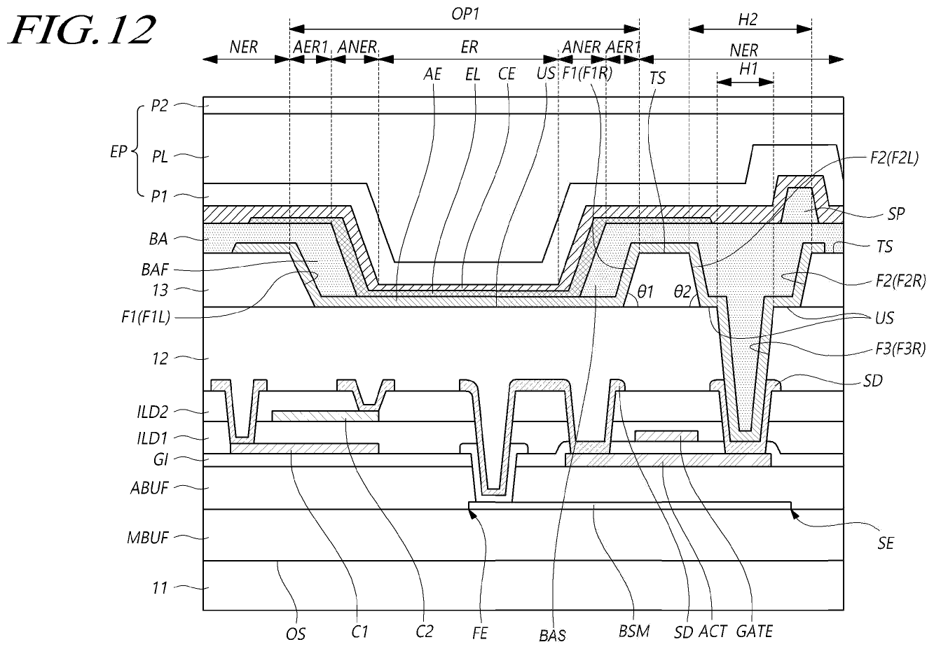

FIG. 12 is a cross-sectional view of the display apparatus according to embodiments of the present specification.

Referring to FIG. 12, a substrate 11 may include a first substrate, an interlayer insulating film, and a second substrate. The interlayer insulating film may be located between the first substrate and the second substrate. For example, the first substrate and the second substrate may be polyimide (PI) substrates. The first substrate may be referred to as a first PI substrate, and the second substrate may be referred to as a second PI substrate. By configuring the substrate 11 as the first substrate, the interlayer insulating film, and the second substrate, moisture penetration may be prevented.

Various patterns ACT, SD, and GATE, various insulating films MBUF, ABUF, GI, ILD1, ILD2, 12, and 13, and various metal patterns for forming transistors, such as thin-film transistors, may be disposed on the substrate 11.

A multi-buffer layer MBUF may be disposed on the substrate 11. A metal layer BSM may be disposed on the multi-buffer layer MBUF. The metal layer BSM may be a light shield layer that blocks (or shields) light.

An active buffer layer ABUF may be disposed on the metal layer BSM. An active layer ACT of the transistor may be disposed on the active buffer layer ABUF. A gate insulating film GI may be disposed to cover the active layer ACT. A gate electrode GATE of the transistor may be disposed on the gate insulating film GI.

A first interlayer insulating film ILD1 may be disposed to cover the gate electrode GATE. A second interlayer insulating film ILD2 may be disposed on the first interlayer insulating film ILD1.

Two connection electrodes SD may be disposed on the second interlayer insulating film ILD2. One of the two connection electrodes SD is a source node of the transistor and the other thereof is a drain node of the transistor.

The two connection electrodes SD may be electrically connected to one side and the other side of the active layer ACT through contact holes pass through the second interlayer insulating film ILD2, the first interlayer insulating film ILD1, and the gate insulating film GI, respectively.

A portion of the active layer ACT overlapping the gate electrode GATE is a channel area. One of the two connection electrodes SD may be connected to one side of the channel area in the active layer ACT, and the other of the two connection electrodes SD may be connected to the other side of the channel area in the active layer ACT.

The transistor may at least partially overlap the light-emitting element. The display apparatus according to embodiments of the present specification includes a top emission organic electric element, and at least a portion of the transistor may overlap the light-emitting element.

A capacitor may be located above the active buffer layer ABUF. A first capacitor electrode C1 may be located above the active buffer layer ABUF. Alternatively, the first capacitor electrode C1 may be disposed on the same layer as the gate electrode GATE.

A second capacitor electrode C2 may be located on the first interlayer insulating film ILD1. Alternatively, the second capacitor electrode C2 may be disposed on the same layer as the connection electrode SD.

A first protective layer 12 may be disposed to cover the connection electrode SD. A portion of the first protective layer 12 may be open to form the first contact hole H1. One of the connection electrodes SD may be exposed by the first contact hole H1.

A second protective layer 13 may be disposed on the first protective layer 12. A portion of the second protective layer 13 corresponding to the emission area EA of the sub-pixel may be open to form the first opening OP1. At least a portion of the first protective layer 12 may be exposed by the first opening OP1. The first inclined surface F1 of the second protective layer 13 may be exposed by the first opening OP1.

A portion of the second protective layer 13 may be open to form the second contact hole H2. The first contact hole H1 and the first protective layer 12 around the first contact hole H1 may be exposed by the second contact hole H2. A second inclined surface F2 of the second protective layer 13 may be exposed by the second contact hole H2. A bottom portion of the second contact hole H2 may have a dimension larger than that of a top portion of the first contact hole H1.

The first electrode AE may be disposed in an area including the first opening OP1 of the second protective layer 13 and the first and second contact holes H1 and H2. The first electrode AE may be an anode.

The first electrode AE may be disposed on the upper surface of the first protective layer 12 and the first inclined surface F1 of the second protective layer 13, which are exposed through the first opening OP1. In addition, the first electrode AE may be disposed on the second inclined surface F2 of the second protective layer 13 exposed through the second contact hole H2. The first electrode AE may be continuously disposed along the first inclined surface F1 of the second protective layer 13, an upper surface of the second protective layer 13 connected to the first inclined surface F1, and the second inclined surface F2 of the second protective layer 13 connected to the upper surface of the second protective layer 13.

In addition, the first electrode AE may be disposed along the third inclined surface F3 of the first protective layer 12 exposed through the first contact hole H1. The first electrode AE may be continuously disposed along the second inclined surface F2 of the second protective layer 13, the upper surface of the first protective layer 12 connected to the second inclined surface F2, and the third inclined surface F3 of the first protective layer 12 connected to the upper surface of the first protective layer 12.

In addition, the first electrode AE may be disposed on the connection electrode SD exposed through the first contact hole H1, and may be directly connected to the connection electrode SD.

A bank BA may be disposed to cover a portion of the first electrode AE. The bank BA may be disposed on the upper surface of the second protective layer 13 and an edge of the first opening OP1 of the second protective layer 13. The bank BA may be disposed to fill the first and second contact holes H1 and H2. A spacer SA may be disposed on the bank BA in an area between adjacent sub-pixels.

At least a portion of the first electrode AE disposed on a bottom surface of the first opening OP1 may be exposed by the bank BA. The emission layer EL may be located on a side surface of the bank BA and an opening of the bank BA. In the opening of the bank BA, the emission layer EL may be in contact with the first electrode AE. A second electrode CE may be disposed on the emission layer EL. The second electrode CE may be a cathode of the light-emitting element.

The emission layer EL may include an organic material including a fluorescent or phosphorescent material emitting red, green, blue, or white light. The emission layer EL may be a low molecular weight organic material or a high molecular weight organic material.

A first functional layer and a second functional layer may be selectively disposed below and above the emission layer EL.

The first functional layer may include a hole injection layer (HIL) and/or a hole transport layer (HTL), and the second functional layer may include an electron transport layer (ETL) and/or an electron injection layer (EIL).

The first functional layer and the second functional layer disposed below and above the emission layer EL may be integrally formed throughout the substrate 11 to cover a plurality of sub-pixels disposed in the display area using an open mask.

An encapsulation layer EP may be disposed on the second electrode CE.

The encapsulation layer EP may have a single-layer structure or a multi-layer structure. For example, as shown in FIG. 12, the encapsulation layer EP may include a first encapsulation layer P1, a second encapsulation layer PL, and a third encapsulation layer P2.

For example, the first encapsulation layer P1 and the third encapsulation layer P2 may be inorganic films, and the second encapsulation layer PL may be an organic film. Among the first encapsulation layer P1, the second encapsulation layer PL, and the third encapsulation layer P2, the second encapsulation layer PL is the largest in thickness, and may serve as a planarization layer.

The first encapsulation layer P1 may be disposed on the second electrode CE and may be disposed closest to the light-emitting element ED. The first encapsulation layer P1 may be formed of an inorganic insulating material that is capable of being deposited at a low temperature. For example, the first encapsulation layer P1 may be silicon nitride (SiNx), silicon oxide (SiOx), silicon oxynitride (SiON), aluminum oxide (Al₂O₃), or the like. Since the first encapsulation layer P1 is deposited in a low-temperature atmosphere, the first encapsulation layer P1 can prevent the emission layer EL including an organic material vulnerable to a high-temperature atmosphere from being damaged during deposition processing.

The second encapsulation layer PL may be formed in an area smaller than that of the first encapsulation layer P1. In this case, the second encapsulation layer PL may be formed to expose both terminating ends of the first encapsulation layer P1. The second encapsulation layer PL may serve as a buffer for mitigating stress between respective layers caused by bending of the display apparatus, and serve to enhance planarization performance. For example, the second encapsulation layer PL may be an acrylic resin, an epoxy resin, polyimide, polyethylene, silicon oxycarbon (SiOC), or the like, and may be formed of an organic insulating material. For example, the second encapsulation layer PL may be formed by an inkjet method.

The third encapsulation layer P2 may be formed on the substrate 11 on which the second encapsulation layer PL is formed to cover an upper surface and a side surface of each of the second encapsulation layer PL and the first encapsulation layer P1. The third encapsulation layer P2 may minimize or prevent external moisture or oxygen from penetrating into the first and second encapsulation layers P1 and PL. For example, the third encapsulation layer P2 is formed of an inorganic insulating material, such as silicon nitride (SiNx), silicon oxide (SiOx), silicon oxynitride (SiON), aluminum oxide (Al₂O₃), or the like.

The display panel according to the embodiments of the present specification described above may be briefly described as follows.

A display apparatus according to embodiments of the present specification includes a thin-film transistor disposed on a substrate, a first protective layer disposed on the thin-film transistor and including a first contact hole configured to expose a portion of a connection electrode of the thin-film transistor, a second protective layer disposed on the first protective layer and including an opening configured to expose the first protective layer and a second contact hole configured to expose the first contact hole, and a light-emitting element disposed on the opening. A first electrode of the light-emitting element is disposed in an area including the opening and the first and second contact holes and connected to the connection electrode through the first and second contact holes.

According to embodiments of the present specification, a dimension of a bottom portion of the second contact hole may be larger than a dimension of a top portion of the first contact hole.

According to embodiments of the present specification, the second contact hole may expose an outer periphery of a top portion of the first contact hole and at least a portion of an upper surface of the first protective layer around the outer periphery of the top portion of the first contact hole.

According to embodiments of the present specification, an outer periphery of a bottom portion of the second contact hole may be located on the first protective layer.

According to embodiments of the present specification, an inclined surface of the second protective layer exposed through the opening may have a first inclination angle, and an inclined surface of the second protective layer exposed through the second contact hole may have a second inclination angle different from the first inclination angle.

According to embodiments of the present specification, the first inclination angle may be larger than the second inclination angle.

According to embodiments of the present specification, the first electrode may include a first inclined portion disposed on an inclined surface of the second protective layer exposed through the opening and a second inclined portion disposed on an inclined surface of the second protective layer exposed through the second contact hole.

According to embodiments of the present specification, a thickness of the first inclined portion and a thickness of the second inclined portion may be different from each other.

According to embodiments of the present specification, the thickness of the second inclined portion may be larger than the thickness of the first inclined portion.

According to embodiments of the present specification, the opening of the second protective layer and the second contact hole may expose a portion of an upper surface of the first protective layer, and an area of the upper surface of the first protective layer exposed by the second contact hole may be smaller than an area of the upper surface of the first protective layer exposed by the opening.

According to embodiments of the present specification, a bank may be disposed at an edge of the opening of the second protective layer and disposed to fill the first contact hole and the second contact hole.

A display apparatus according to embodiments of the present specification may include a first protective layer located on a substrate and including a first contact hole, a second protective layer located in a partial area on the first protective layer and including an opening and a second contact hole, and a first electrode disposed in an area including the opening, the first contact hole, and the second contact hole, and disposed along a first inclined surface of the second protective layer exposed by the opening and having a first inclination angle and a second inclined surface of the second protective layer exposed by the second contact hole and having a second inclination angle smaller than the first inclination angle.

According to embodiments of the present specification, the first electrode may be disposed along a third inclined surface of the first protective layer exposed through the first contact hole in an area including the second contact hole.

According to embodiments of the present specification, the first electrode may be continuously disposed along the second inclined surface of the second protective layer, an upper surface of the first protective layer connected to the second inclined surface, and the third inclined surface of the first protective layer connected to the upper surface of the first protective layer.

According to embodiments of the present specification, the first electrode may have a stepped shape.

Through such a structure, according to embodiments of the present specification, there is an effect of providing a display apparatus allowing the number of process steps and masks required to connect a light-emitting element and thin-film transistors to be reduced by disposing a second contact hole, which is formed in a second protective layer, so as to overlap a first contact hole formed in a first protective layer below a second protective layer, and by directly connecting the first electrode to a substrate through the first and second contact holes without a separate contact.

In addition, according to embodiments of the present specification, there is an effect of providing a display apparatus capable of suppressing or preventing the generation of an undercut even when misalignment occurs between contact holes and thus suppressing or preventing a defect in which a first electrode is disconnected due to the undercut, by configuring a bottom portion of the second contact hole to have a larger dimension than a top portion of the first contact hole.

In addition, according to embodiments of the present specification, there is an effect of providing a display apparatus capable of increasing light extraction efficiency by configuring a first inclined portion of a first electrode, which serves to reflect light emitted from an emission layer, to have a high inclination angle.

In addition, according to embodiments of the present specification, there is an effect of providing a display apparatus capable of improving step coverage by configuring a sidewall of a second contact hole to have a low inclination angle, and capable of suppressing or preventing a connection failure between a light-emitting element and a thin-film transistor by increasing a thickness of a first electrode formed on the sidewall of the second contact hole.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display apparatus comprising:
a thin-film transistor disposed on a substrate, the thin-film transistor having a connection electrode;
a first protective layer disposed on the thin-film transistor and including a first contact hole configured to expose a portion of the connection electrode of the thin-film transistor;
a second protective layer disposed on the first protective layer and including an opening configured to expose the first protective layer and a second contact hole configured to expose the first contact hole; and
a light-emitting element disposed on the opening,
wherein a first electrode of the light-emitting element is disposed in an area including the opening and the first and second contact holes, and
wherein the first electrode of the light-emitting element is electrically connected to the connection electrode through the first and second contact holes.

2. The display apparatus of claim 1, wherein a dimension of a bottom portion of the second contact hole is larger than a dimension of a top portion of the first contact hole.

3. The display apparatus of claim 1, wherein the second contact hole exposes an outer periphery of a top portion of the first contact hole and at least a portion of an upper surface of the first protective layer around the outer periphery of the top portion of the first contact hole.

4. The display apparatus of claim 1, wherein an outer periphery of a bottom portion of the second contact hole is located on the first protective layer.

5. The display apparatus of claim 1, wherein a first inclined surface of the second protective layer exposed through the opening has a first inclination angle, and
wherein a second inclined surface of the second protective layer exposed through the second contact hole has a second inclination angle different from the first inclination angle.

6. The display apparatus of claim 5, wherein the first inclination angle is larger than the second inclination angle.

7. The display apparatus of claim 1, wherein the first electrode includes a first inclined portion disposed on an inclined surface of the second protective layer exposed through the opening and a second inclined portion disposed on an inclined surface of the second protective layer exposed through the second contact hole.

8. The display apparatus of claim 1, wherein a thickness of the first inclined portion and a thickness of the second inclined portion are different from each other.

9. The display apparatus of claim 8, wherein the thickness of the second inclined portion is larger than the thickness of the first inclined portion.

10. The display apparatus of claim 1, wherein the opening of the second protective layer and the second contact hole exposes a portion of an upper surface of the first protective layer, and
wherein an area of the upper surface of the first protective layer exposed by the second contact hole is smaller than an area of the upper surface of the first protective layer exposed by the opening.

11. The display apparatus of claim 1, further comprising a bank disposed at an edge of the opening of the second protective layer and disposed to fill the first contact hole and the second contact hole.

12. A display apparatus comprising:
a first protective layer located on a substrate and including a first contact hole;
a second protective layer located in a partial area on the first protective layer and including an opening and a second contact hole; and
a first electrode disposed in an area including the opening, the first contact hole, and the second contact hole, and disposed along a first inclined surface of the second protective layer exposed by the opening and having a first inclination angle and a second inclined surface of the second protective layer exposed by the second contact hole and having a second inclination angle smaller than the first inclination angle.

13. The display apparatus of claim 12, wherein the first electrode is disposed along a third inclined surface of the first protective layer exposed through the first contact hole in an area including the second contact hole.

14. The display apparatus of claim 13, wherein the first electrode is continuously disposed along the second inclined surface of the second protective layer, an upper surface of the first protective layer connected to the second inclined surface, and the third inclined surface of the first protective layer connected to the upper surface of the first protective layer.

15. The display apparatus of claim 12, wherein the first electrode has a stepped shape.

16. A display apparatus comprising:
a light-emitting element on a substrate, the light-emitting element including a first electrode, a second electrode spaced from the first electrode, and an emission layer between the first and second electrodes;
a first protective layer on the substrate, the first protective layer having a first upper surface and a first inclined side surface extending from the first upper surface;
a first contact hole extending through the first protective layer, a sidewall of the first contact hole corresponding to the first inclined side surface of the first protective layer;
a second protective layer on the first protective layer, the second protective layer having a second upper surface and a second inclined side surface extending from the second upper surface; and
a second contact hole extending through the second protective layer, a sidewall of the second contact hole corresponding to the second inclined side surface of the second protective layer,
wherein the first electrode extends from the light-emitting element and is continuously and contiguously disposed over the second inclined side surface and the second upper surface of the second protective layer and the first upper surface and the first inclined side surface of the first protective layer.

17. The display apparatus of claim 16, wherein a dimension of the second contact hole in a first direction is greater than a corresponding dimension of the first contact hole in the first direction such that the second contact hole fully overlaps the first contact hole from a plan view.

18. The display apparatus of claim 16, wherein the emission layer extends from the light-emitting element and is disposed over the second upper surface and the second inclined surface of the second protective layer.

19. The display apparatus of claim 18, comprising:
a bank layer on the second protective layer,
wherein the bank layer is deposited within the first contact hole and the second contact hole.

20. The display apparatus of claim 19, wherein the second protective layer includes a third inclined surface (F1) that is opposite the second inclined surface, and
wherein at least a portion of the bank layer is between the third inclined surface of the second protective layer and the emission layer.

21. The display apparatus of claim 20, wherein the second electrode extends from the light-emitting element and is continuously and contiguously disposed over the bank layer, and
wherein the second electrode further overlaps the third inclined surface, the second inclined side surface, and the second upper surface of the second protective layer and the first upper surface and the first inclined side surface of the first protective layer from a plan view.

22. The display apparatus of claim 16, wherein the second inclined surface of the second protective layer form a first angle with respect to the first upper surface of the first protective layer,
wherein the second protective layer includes a third inclined surface that is opposite the second contact hole and opposite the second inclined surface,
wherein third inclined surface of the second protective layer form a second angle with respect to the first upper surface of the first protective layer,
wherein the first angle is different from the second angle.

23. The display apparatus of claim 22, wherein the first angle is smaller than the second angle.

24. The display apparatus of claim 16, wherein the second inclined surface of the second protective layer form a first angle with respect to the first upper surface of the first protective layer,
wherein the second protective layer includes a third inclined surface that is opposite the second contact hole and opposite the second inclined surface,
wherein third inclined surface of the second protective layer form a second angle with respect to the first upper surface of the first protective layer,
wherein a first portion of the first electrode that is disposed over the second inclined surface has a first thickness and a second portion of the first electrode that is disposed over the third inclined surface has a second thickness, and
wherein the first thickness is different from the second thickness.

25. The display apparatus of claim 24, wherein the first thickness is greater than the second thickness.

26. The display apparatus of claim 24, wherein the first inclined side surface of the first protective layer and the second inclined side surface of the second protective layer are coplanar with each other, and
wherein a dimension of the second contact hole in a first direction is greater than a corresponding dimension of the first contact hole in the first direction such that the second contact hole fully overlaps the first contact hole from a plan view.
